(19) United States
(12) Patent Application Publication
(10) Pub. No.: US 2020/0271971 A1
(43) Pub. Date: Aug. 27, 2020

(54) TILED DISPLAY AND MANUFACTURING METHOD THEREOF

(71) Applicant: HUIZHOU CHINA STAR OPTOELECTRONICS TECHNOLOGY CO., LTD., Huizhou Guangdong (CN)

(72) Inventor: Zanjia SU, Shenzhen, Guangdong (CN)

(21) Appl. No.: 15/781,755

(22) PCT Filed: Mar. 20, 2018
(86) PCT No.: PCT/CN2018/079557

§ 371 Date: Jun. 6, 2018

(30) Foreign Application Priority Data
Feb. 2, 2018 (CN) 201810106178.2

(51) Int. Cl. G02F 1/1333; G09F 9/35; H05K 5/00; H05K 1/18

(52) U.S. Cl. CPC G02F 1/13336; G02F 1/133308; G09F 9/35; H05K 2201/10136; H05K 1/189; G02F 2202/28; H05K 5/0017

(57) ABSTRACT

The manufacturing method for a tiled display includes the following steps. First, an adhesive layer is formed on a substrate. Then, a number of display panels are tiled on the adhesive layer. The bezel regions of the display panels are joined tightly or with a gap in between. These display panels are then assembled into a display module, and the display regions of the display panels jointly form a display region of the display module. Through the adhesive layer and the substrate, multiple display panels are completely attached to the substrate and their bezel regions are joined tightly together or with a gap as a single module. In contrast to the prior art where individual display panel is formed into a module first and the modules are tiled together, the present invention effectively reduces assembly tolerance and prevents reserved gap for thermal expansion being too wide.

### CROSS-REFERENCE TO RELATED APPLICATIONS

This application is a national phase entry of PCT Patent Application No. PCT/CN2018/079557, filed on Mar. 20, 2018, which claims priority to Chinese Patent Application No. 201810106178.2, filed on Feb. 2, 2018, both of which are hereby incorporated herein by reference in their entireties.

### FIELD OF THE INVENTION

The present invention is generally related to display technologies, and more particular to a tiled display and a related manufacturing method.

### BACKGROUND OF THE INVENTION

Displays are widely applied in televisions, monitors, and industrial and medical products. There are also more displays utilized in public areas. For public usage, the displays are required to have a greater dimension so that they may be viewed from a greater distance and able to present more information. For existing Tiled display (LCD) technology, the mainstream dimension is between 32 to 35 inches. In order to be used in public, LCDs of this order of dimension are usually tiled together into a larger display.

When multiple panels are tiled together, their respective bezels are bordered together into obvious gaps. Various manufacturers therefore investigate approaches to reduce the gaps as much as possible. Currently, the gaps may be reduced to between 3.5 and 5.5 mm. For some high-end products, the gap may even be reduced to 1.4 mm. However, such an ideal gap is difficult to attain because some assembly tolerance and room for expansion has to be reserved.

Therefore a solution is required so as to approach the ideal gaps for a tiled display.

### SUMMARY OF THE INVENTION

An objective of the present invention is to provide a tiled display and a related manufacturing method so that the tiled display approaches an ideal configuration.

To achieve the objective, the present invention provides the following technical solutions.

In a first technical solution, a manufacturing method for a tiled display includes the following steps.

An adhesive layer is formed on a substrate by coating adhesive on the substrate.

A number of display panels are tiled on the adhesive layer, where each display panel comprises a display region and a bezel region surrounding the display region, and the bezel regions of the display panels are joined tightly or with a gap in between.

The display panels on the substrate are assembled into a display module, where the display regions of the display panels jointly form a display region of the display module.

In a first embodiment of the first technical solution, at least a connection piece is configured on each display panel, and the connection piece is disposed along the bezel region of the display panel adjacent to the substrate's edge.

In a second embodiment based on the first embodiment, the display panels are surrounded in a frame, and the connection pieces are stored in the frame.

In a third embodiment based on the above embodiment, each connection piece includes a flexible circuit board and a printed circuit board, the flexible circuit board is connected between the display panel and the printed circuit board, and the flexible circuit board is bended so that it and the printed circuit board are stored in the frame.

In a fourth embodiment based on the first technical solution, the manufacturing method further include the following step.

A backlight module is provided and disposed to a side of the substrate opposite to the adhesive layer, wherein the backlight module has a planar size identical to that of the substrate.

In a fifth embodiment based on the first technical solution, at least a bulge is provided along the bezel region of each display panel; and neighboring display panels are separated by the bulges to form the gap.

In a second technical solution, a tiled display is provided. The tiled display includes a substrate, an adhesive layer on the substrate, and a number of display panels attached to the adhesive layer. Each display panel includes a display region and a bezel region surrounding the display region, the bezel regions of the display panels are joined tightly or with a gap in between, the display panels on the substrate are assembled into a display module, and the display regions of the display panels jointly form a display region of the display module.

In a first embodiment of the second technical solution, at least a connection piece is configured on each display panel, and the connection piece is disposed along the bezel region of the display panel adjacent to the substrate's edge.

In a second embodiment based on the previous embodiment, the display panels are surrounded in a frame, and the connection pieces are stored in the frame.

In a third embodiment based on the previous embodiment, each connection piece includes a flexible circuit board and a printed circuit board, the flexible circuit board is connected between the display panel and the printed circuit board, and the flexible circuit board is bended so that it and the printed circuit board are stored in the frame.

The advantages of the present invention are as follows.

Through the adhesive layer and the substrate, multiple display panels are completely attached to the substrate and their bezel regions are joined tightly together or with a gap as a single module. In contrast to the prior art where individual display panel is formed into a module first and the modules are tiled together, the present invention effectively reduces assembly tolerance and prevents reserved gap for thermal expansion being too wide. The tiled display therefore may approach its ideal configuration.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a perspective diagram showing a substrate of a tiled display according to an embodiment of the present invention.

FIG. 2 is a perspective diagram showing an adhesive layer coated on the substrate of FIG. 1.

FIG. 3 is a perspective diagram showing a first display panel disposed on the substrate of FIG. 2.

FIG. 4 is a perspective diagram showing a second display panel disposed on the substrate of FIG. 3.

FIG. 5 is a perspective diagram showing a third display panel disposed on the substrate of FIG. 4.

FIG. 6 is a perspective diagram showing a fourth display panel disposed on the substrate of FIG. 5.

FIG. 7 is a planar diagram showing a first display panel and a second display panel being pieced together according to another embodiment of the present invention.

FIG. 8 is a perspective diagram showing a backlight module disposed behind the substrate of FIG. 6.

FIG. 9 is a perspective diagram showing the tiled display of FIG. 8 being housed in a frame as a display module.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

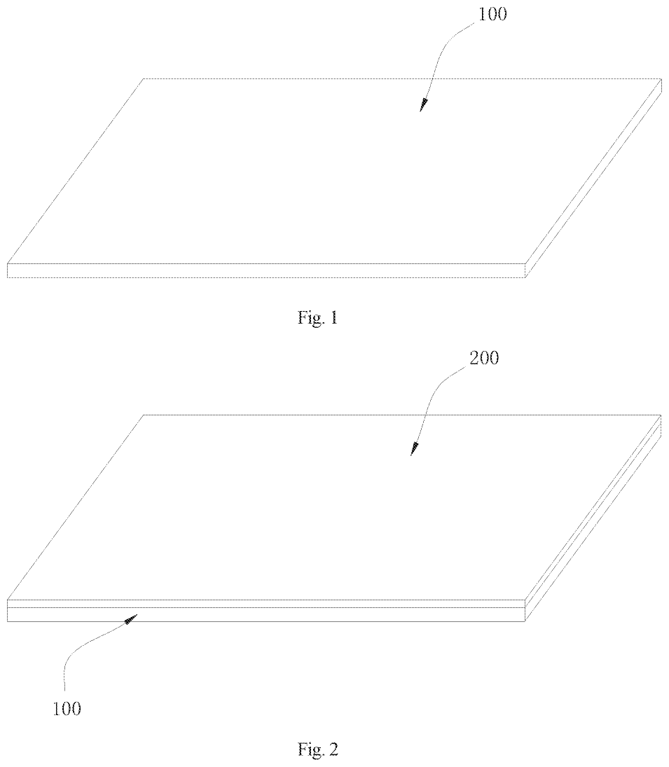

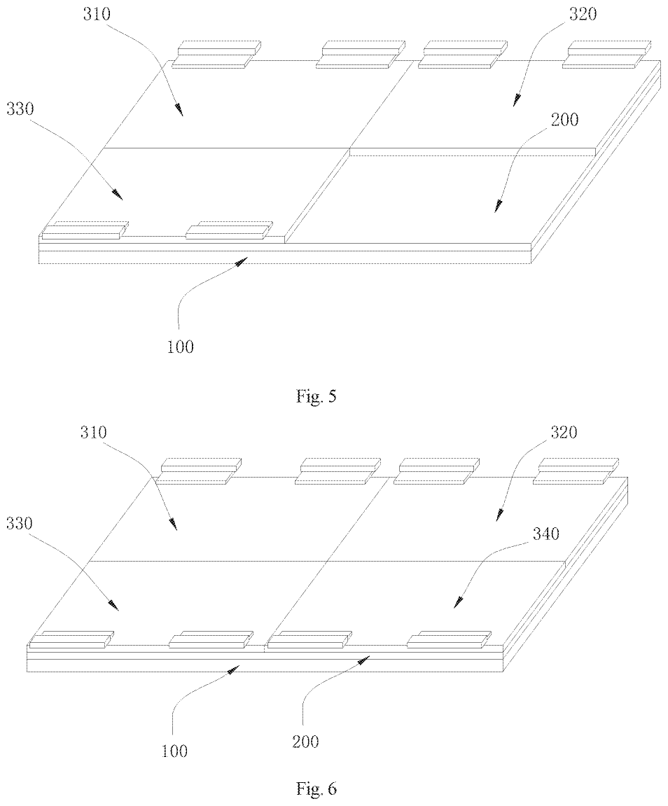

As shown in FIGS. 1 to 9, a manufacturing method for a tiled display according to an embodiment of the present invention includes the following steps.

An adhesive is applied a substrate 100 and an adhesive layer 200 is formed to cover the substrate 100.

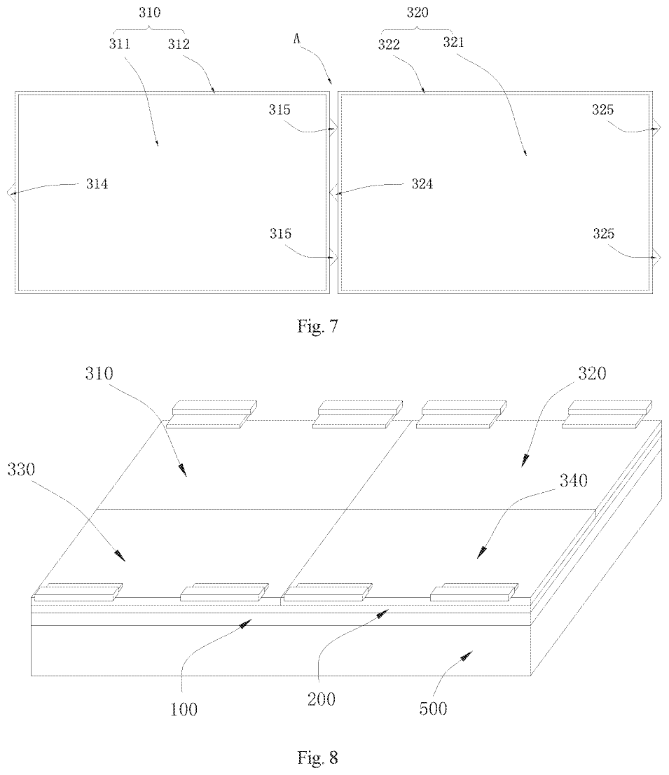

A number of display panels are tiled on the adhesive layer 200. Each display panel include a display region (not shown in FIGS. 1 to 6, but marked as 311 and 321 in FIG. 7, respectively) and a bezel region (not shown in FIGS. 1 to 6, but marked as 312 and 322 in FIG. 7, respectively). The bezel region surrounds the display region. The bezel regions of the display panels are bordered together, either directly or with a gap in between. Specifically, these display panels include a first display panel 310 up to the (N×M)th display panel tightly bordered together. Both N and M are positive integers at least 1.

These display panels are pieced together into a single display module. The display regions of the display panels jointly form the display region for the display module. Specifically, the first display panel 310 up to the (N×M)th display panel are pieced together into the display module.

In the present embodiment, N and M are row and column numbers of the display panels when they are layout on the substrate 100. That is, the display panels are arranged in an array. N×M is greater than 2 and there are at least two display panels involved. The present embodiment has N=2 and M=2. It should be understandable that N and M may be any positive integer and N×M could be 1×2, 1×3, 2×3, 3×3, etc.

As shown in FIGS. 4 to 6, the first and second display panels 310 and 320 are attached to the adhesive layer 200 first, the third and fourth display panels 330 and 340 are attached subsequently, thereby forming a display module with 2×2 display panels.

As shown in FIG. 7, the first display panel 310 includes a first display region 311 and a first bezel region 312. The second display panel 320 includes a second display region 321 and a second bezel region 322. FIGS. 1 to 6 show an embodiment where neighboring display panels are tightly joined together. FIG. 7 shows another embodiment where a gap A is reserved between neighboring display panels. As shown in FIG. 7, at least a laterally extended bulge is provided along its bezel region, and neighboring display panels are separated by the bulges into having a gap in between. Specifically, one first bulge 314 is provided in a middle location of a vertical section, and two second bulges 315 are provided symmetrically about the middle location along an opposite vertical section, of the first bezel region 312 of the first display panel 310. The first and second bulges 314 and 315 are not required to have a specific shape. They may have a triangular, rectangular, or circular shape. Corresponding to the first display panel 310, one third bulge 324 and two fourth bulges 325 are provided along the second bezel region 322 of the second display panel 320, configured at the same locations as the first and second bulges 314 and 315. In alternative embodiments, there may be different numbers of first and second bulges 314 and 315. In the present embodiment, the bulges result in the fixed gap A. Then, by simply having the second bulges 315 of the first display panel 310 pressed against the second display panel 320, and the third bulge 324 of the second panel 320 pressed against the first display panel 310, the gap A is precisely formed. It should be understandable that the other display panels are configured with bulges identical to the first and second display panels 310 and 320. Through these bulges, the display panels may be quickly aligned and pieced together.

As shown in FIG. 6, the first and second display panels 310 and 320 have one of their vertical sections in the bezel regions tightly joined together. The first and third display panels 310 and 330 have one of their lateral sections in the bezel regions tightly joined together. The first display panel 310 therefore has a pair of neighboring vertical and lateral sections of its bezel region joined to the bezel regions of the second and third display panels 320 and 330, respectively. The fourth display panel 340 has a pair of neighboring vertical and lateral sections of its bezel region joined to the bezel regions of the second and third display panels 320 and 330, respectively. As the first to the fourth display panels 310 to 340 are rectangle-shaped, the display module pieced together by these display panels is also rectangle-shaped.

In the present embodiment, the width of the bezel region may be adjusted based on requirement. For example, if the distance between neighboring pixels is larger, the width of the bezel region may also be larger, but usually should not be greater than the distance of neighboring pixels. As such, the bezel regions may not be visible if the display module is viewed from an appropriate distance. Under a special circumstance, the bezel region may have a zero width, meaning that the bezel region is omitted. Then, the display panel's size is its display region's size. To piece this kind of display panels together, they may be joined either tightly together or with a gap in between.

The purpose of having a reserve gap between display panels is to allow for thermal expansion so that the display panels do not perk up when temperature is high. The width of the gap may also be adjusted based on product requirement. As far as the existing technology is concerned, since the bezel region may be as small as possible, the gap and the bezel region together may also be quite small.

Through coating an adhesive layer 200 on the substrate 100, multiple display panels are completely attached to the substrate 100 and their bezel regions are tightly joined together as a single module. In contrast to the prior art where individual display panel is formed into a module first and the modules are tiled together, the present invention may effectively reduce assembly tolerance and prevent reserved gap for thermal expansion being too wide, thereby achieving a tiled display more closely to the ideal configuration.

In the present embodiment, the multiple display panels may be completely attached to the adhesive layer 200 on the substrate 100, meaning that the display panels may have zero distance to the adhesive layer 200. As such, the tiled display of the present invention has a smaller distance between the display panels and the substrate 100 than that of the prior art. The backlight may be more uniformly incident into the display panels. Furthermore, the substrate should have a transmittance between 40% and 95% so that light from a backlight module 500 may pass through the substrate 100. The transmittance of the substrate is better to be between 50% and 95%, preferably between 70% and 95% so that the substrate 100 is semi-transparent or transparent. When the display panels 200 are Tiled display (LCD) panels, light therefore may pass through the substrate 100 and function as backlight to the LCD panels. The substrate 100 may be made of glasses, quartz, or polymethyl methacrylate (PMMA). The thickness of the substrate 100 is between 0.5 and 5 mm, better between 1 to 3 mm, and preferably between 1 and 2 mm, so that it has appropriate strength to support the display panels with a limited thickness. The planar dimension of the substrate 100 could be identical to or slightly larger than the combined size of the N×M display panels. The adhesive layer 200 may be made of solid Optical Clear Adhesive (OCA), hot melt OCF, water gel, AB glue, or other adhesives. The thickness of the adhesive layer 200 is between 0.1 to 2.5 mm, preferably between 0.5 and 1.0 mm, so that the adhesive layer 200 may be reliably adhered the display panels with a limited thickness. In one embodiment, the adhesive layer 200 is formed on the display panels and the display panels are then attached to the substrate 100.

The first, second, third, and fourth display panels 310, 320, 330, and 340 may be LCD panels. In this case, as shown in FIG. 8, the present embodiment also involves the following steps.

A backlight module 500 is provided. The backlight module 500 has a planar size identical to that of the substrate 100, and is disposed to a side of the substrate 100 opposite to the adhesive layer 200.

The first, second, third, and fourth display panels 310, 320, 330, and 340 may also be Organic Light Emitting Diode (OLED) or Micro LED display panels. In this case, no backlight module 500 is required.

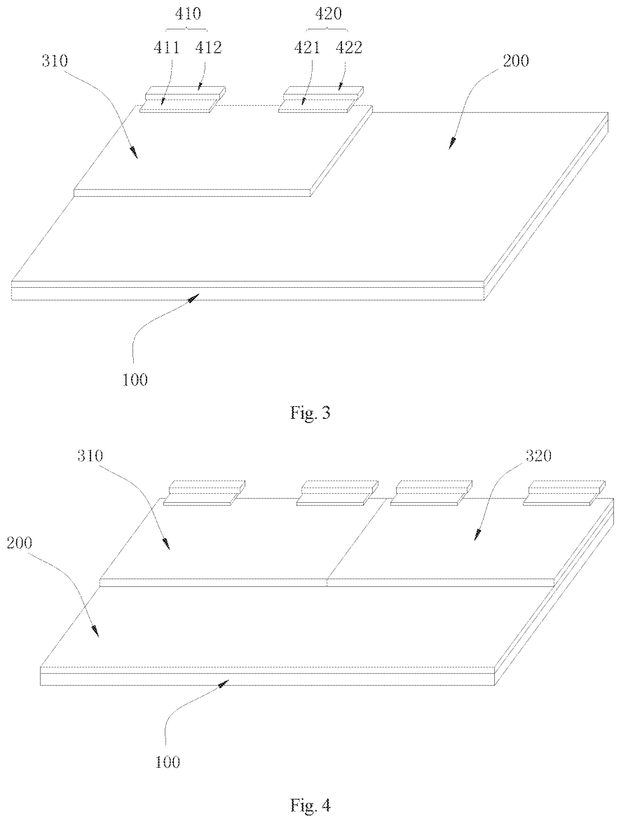

In one embodiment, as shown in FIGS. 3 to 6, at least a connection piece is disposed along each display panel's bezel region that is adjacent to the substrate's edge. Specifically, as shown in FIG. 3, a first connection piece 410 is disposed to a lateral section of the bezel region of the first display panel 310 adjacent to the substrate 100's edge. There may be multiple connection pieces. For instance, as shown in FIG. 3, there are a first connection piece 410 and a second connection piece 420. It should be understandable, as shown in FIGS. 4 to 8, the second to fourth display panels 320 to 340 are configured with connection pieces (not numbered) similar to the first display panel 310. All these connection pieces are disposed along lateral sections of the bezel regions adjacent to the edge of the substrate 100. As such, these connection pieces do not take up any space in the display regions, and the first to fourth display panels 310 to 340 as such are able to provide a complete and integral display region.

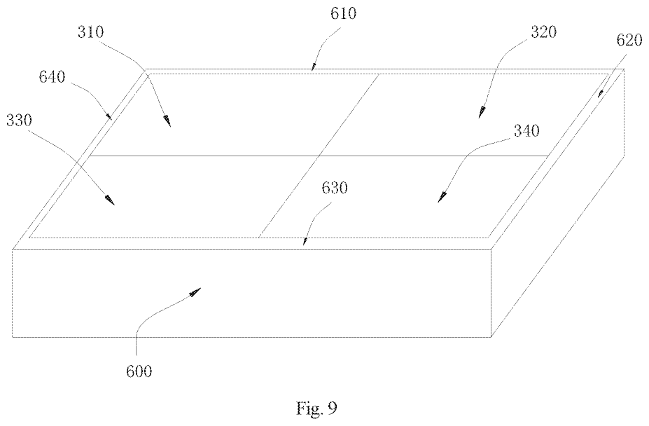

In one embodiment, as shown in FIG. 9, the tiled display panels are accommodated in a frame. Specifically, the first to fourth display panels 310 to 340 are accommodated within and surrounded by a frame 600. As such, the first to fourth display panels 310 to 340 jointly form a large display module.

In addition, the frame 600 fixes the first to fourth display panels 310 to 340. The flame 600 has identical lateral sides as those of the display panels. Each lateral sides of the flame 600 has an inner wall contacting the display panels 310 to 340, and an outer wall opposite to the inner wall. The thickness between the inner and outer walls is the bezel width of the display module. This bezel width may be adjusted based on requirement. Preferably, this bezel width should not be lower than the width of the bezel regions of the display panels.

Specifically, the frame 600 includes a first frame section 610 contacting the first and second display panels 310 and 320, a second frame section 620 contacting the second and fourth display panels 320 and 340, a third frame section 630 contacting the third and fourth display panels 330 and 340, and a fourth frame section 610 contacting the first and third display panels 310 and 330. The firs to fourth frame sections 610 to 640 are end-to-end connected together, surrounding an accommodation space for housing the first to fourth display panels 310 to 340. The firs to fourth frame sections 610 to 640 may be coplanar, and may be coplanar with or slight above the display regions of the first to fourth display panels 310 to 340. The firs to fourth frame sections 610 to 640 have an identical thickness so that the display module has a uniform bezel width.

In one embodiment, as shown in FIGS. 8 and 9, each connection piece includes a flexible circuit board and a printed circuit board. The flexible circuit board is connected between the display panel and the printed circuit board. Due to its flexibility, the flexible circuit board and the printed circuit board may be folded and stored inside the frame 600 as well. Specifically, as shown in FIGS. 3 and 7, the first connection piece 410 includes a first flexible circuit boar 411 and a first printed circuit board 412, and the first flexible circuit boar 411 is connected between the first bezel region 3122 of the first display panel 310 and the first printed circuit board 412. The first flexible circuit board 411 may be bended so that it and the first printed circuit board 412 may be folded and stored inside the frame 600. The first flexible circuit board 411 is for signal transmission. The first printed circuit board 412 may have elements such as driver IC, resistors, capacitors, and inductors, for driving and controlling the first display panel 310. Similarly, the second connection piece 420 includes a second flexible circuit boar 421 and a second printed circuit board 422. The third and fourth display panels 330 and 340 also have connection pieces similar to the first connection piece 410, and their details therefore are omitted.

As shown in FIGS. 6 to 9, a tiled display according to an embodiment of the present invention includes a substrate 100 and a number of display panels. The substrate 100 is coated with adhesive on a side, thereby forming an adhesive layer 200. The display panels are tiled on the adhesive layer 200. Each display panel includes a display region and a bezel region surrounding the display region. The display panels have their bezel regions tightly joined together or with a gap in between. These display panels are pieced together into a single display module. The display regions of the display panels jointly form the display region for the display module.

Specifically, these display panels include a first display panel 310 up to the (N×M)th display panel. Both N and M are positive integers at least 1. The first display panel 310 up to the (N×M)th display panel are tiled on the adhesive layer 200.

In the present embodiment, through coating an adhesive layer 200 on the substrate 100, multiple display panels are completely attached to the substrate 100 and their bezel regions are tightly joined together as a single module. In contrast to the prior art where individual display panel is formed into a module first and the modules are tiled together, the present invention may effectively reduce assembly tolerance and prevent reserved gap for thermal expansion being too wide, thereby achieving a tiled display more closely to the ideal configuration.

In one embodiment, as shown in FIGS. 3 and 7, a first connection piece 410 is disposed to a lateral section of the bezel region of the first display panel 310 adjacent to the substrate 100's edge. There may be multiple connection pieces. For instance, as shown in FIG. 3, there are a first connection piece 410 and a second connection piece 420. It should be understandable, as shown in FIGS. 4 to 7, the second to fourth display panels 320 to 340 are configured with connection pieces (not numbered) similar to the first display panel 310. All these connection pieces are disposed along lateral sections of the bezel regions adjacent to the edge of the substrate 100. As such, these connection pieces do not take up any space in the display regions, and the first to fourth display panels 310 to 340 as such are able to provide a complete and integral display region.

In one embodiment, as shown in FIG. 8, the first to fourth display panels 310 to 340 are accommodated within and surrounded by a frame 600. As such, the first to fourth display panels 310 to 340 jointly form a large display module.

In one embodiment, as shown in FIG. 3, the first connection piece 410 includes a first flexible circuit boar 411 and a first printed circuit board 412, and the first flexible circuit boar 411 is connected between the first bezel region 3122 of the first display panel 310 and the first printed circuit board 412. The first flexible circuit board 411 may be bended so that it and the first printed circuit board 412 may be folded and stored inside the frame 600. The first flexible circuit board 411 is for signal transmission. Similarly, the second connection piece 420 includes a second flexible circuit boar 421 and a second printed circuit board 422. The third and fourth display panels 330 and 340 also have connection pieces similar to the first connection piece 410, and their details therefore are omitted.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the claims of the present invention.

I claim:

1. A manufacturing method for a tiled display, comprising
forming an adhesive layer on a substrate by coating adhesive on the substrate;
tiling a plurality of display panels on the adhesive layer, where each display panel comprises a display region and a bezel region surrounding the display region, and the bezel regions of the display panels are joined tightly or with a gap in between; and
assembling the display panels on the substrate into a display module, where the display regions of the display panels jointly form a display region of the display module.

2. The manufacturing method according to claim 1, wherein at least a connection piece is configured on each display panel; and the connection piece is disposed along the bezel region of the display panel adjacent to the substrate's edge.

3. The manufacturing method according to claim 2, further comprising
providing a frame to surround the display panels, and storing the connection pieces in the frame.

4. The manufacturing method according to claim 3, wherein each connection piece comprises a flexible circuit board and a printed circuit board, the flexible circuit board is connected between the display panel and the printed circuit board; the flexible circuit board is bended so that it and the printed circuit board are stored in the frame.

5. The manufacturing method according to claim 1, further comprising
providing a backlight module and disposing the backlight module to a side of the substrate opposite to the adhesive layer;
wherein the backlight module has a planar size identical to that of the substrate.

6. The manufacturing method according to claim 1, wherein at least a bulge is provided along the bezel region of each display panel; and neighboring display panels are separated by the bulges to form the gap.

7. A tiled display, comprising
a substrate;
an adhesive layer on the substrate; and
a plurality of display panels attached to the adhesive layer;
wherein each display panel comprises a display region and a bezel region surrounding the display region; the bezel regions of the display panels are joined tightly or with a gap in between; the display panels on the substrate are assembled into a display module; and the display regions of the display panels jointly form a display region of the display module.

8. The tiled display according to claim 7, wherein at least a connection piece is configured on each display panel; and the connection piece is disposed along the bezel region of the display panel adjacent to the substrate's edge.

9. The tiled display according to claim 8, wherein the display panels are surrounded in a frame; and the connection pieces are stored in the frame.

10. The tiled display according to claim 9, wherein each connection piece comprises a flexible circuit board and a printed circuit board; the flexible circuit board is connected between the display panel and the printed circuit board; the flexible circuit board is bended so that it and the printed circuit board are stored in the frame.
